(19) United States
(12) Patent Application Publication
(10) Pub. No.: US 2011/0132653 A1
(43) Pub. Date: Jun. 9, 2011

(54) COAXIAL CABLE SHIELDING

(75) Inventor: Noah Montena, Syracuse, NY (US)

(73) Assignee: JOHN MEZZALINGUA ASSOCIATES, INC., East Syracuse, NY (US)

(21) Appl. No.: 12/631,656

(22) Filed: Dec. 4, 2009

(51) Int. Cl. H05K 9/00

(52) U.S. Cl. 174/350

(57) ABSTRACT

Coaxial cable shielding. In one example embodiment, a coaxial cable includes a center conductor surrounded by a dielectric, a conductive tape surrounding the dielectric, and a jacket surrounding the conductive tape. The conductive tape includes a conductive layer and a bonding agent layer immediately adjacent to the conductive layer. The conductive tape defines first and second edge sections that each borders an interior section. The conductive tape is wrapped around the dielectric such that the first edge section overlaps with the second edge section. The bonding agent layer extends over only at most a portion of the first edge section such that at least a portion of the conductive layer in the first edge section is immediately adjacent to at least a portion of the conductive layer in the second edge section.

### BACKGROUND

Typical coaxial cable includes radio frequency (RF) shielding. One common type of shielding is a conductive tape that attenuates interfering electromagnetic radiation in the high frequency range.

With reference first to FIG. 1A, a prior art coaxial cable 100 is disclosed. As disclosed in FIG. 1A, the coaxial cable 100 is terminated on either end with a connector 150. With reference now to FIG. 1B, the prior art coaxial cable 100 generally includes a center conductor 102 surrounded by a dielectric 104, a conductive tape 106 wrapped longitudinally around the dielectric, a braid 108 surrounding the conductive tape 106, and a jacket 110 surrounding the braid 108.

With reference now to FIG. 1C, the conductive tape 106 surrounds the dielectric 104, and generally serves to limit the ingress and egress of high frequency electromagnetic radiation 112 to/from the center conductor 102. The conductive tape 106 is a laminate tape that includes an aluminum layer 114 and a polymer bonding agent layer 116. The conductive tape 106 also defines a first edge section 118 that overlaps a second edge section 120 as the conductive tape 106 is wrapped around the longitudinal direction of the dielectric 104, resulting in an overlapping seam.

With continuing reference to FIG. 1C, and with reference also to FIG. 1D, a common problem with the conductive tape 106 of the prior art coaxial cable 100 is disclosed. In particular, although the aluminum layer 114 is generally effective at shielding high frequency electromagnetic radiation 112, since the polymer bonding agent layer 116 is formed from dielectric material, the layer 116 is not effective at shielding electromagnetic radiation 112. As a result, some high frequency electromagnetic radiation 112 from the center conductor 102 exits the prior art coaxial cable 100 by traveling through an overlap aperture 122 of the polymer bonding agent layer 116. This high frequency electromagnetic radiation 112 that exits the prior art coaxial cable 100 causes harmful interference with surrounding electrical equipment (not shown). Some high frequency electromagnetic radiation from surrounding electrical equipment (not shown) also enters the prior art coaxial cable 100 through the overlap aperture 122, thus causing harmful interference with data signals that are traveling through the center conductor 102.

### SUMMARY OF SOME EXAMPLE EMBODIMENTS

In general, example embodiments of the present invention relate to coaxial cable shielding. Some example embodiments eliminate overlap apertures at overlapping edges of a conductive tape during the manufacturing of a coaxial cable. In coaxial cable, this elimination of overlap apertures results in an increase in the uniformity of the shielding of interfering high frequency electromagnetic radiation.

In one example embodiment, a coaxial cable includes a center conductor surrounded by a dielectric, a conductive tape surrounding the dielectric, and a jacket surrounding the conductive tape. The conductive tape includes a conductive layer and a bonding agent layer immediately adjacent to the conductive layer. The conductive tape defines first and second edge sections that each borders an interior section. The conductive tape is wrapped around the dielectric such that the first edge section overlaps with the second edge section. The bonding agent layer extends over only at most a portion of the first edge section such that at least a portion of the conductive layer in the first edge section is immediately adjacent to at least a portion of the conductive layer in the second edge section.

In another example embodiment, a coaxial cable includes a center conductor surrounded by a dielectric, a conductive tape surrounding the dielectric, a braid surrounding the conductive tape, and a jacket surrounding the braid. The conductive tape includes a conductive layer and a polymer bonding agent layer immediately adjacent to the conductive layer. The conductive tape defines first and second edge sections that each borders an interior section. The conductive tape is wrapped around the dielectric such that the first edge section overlaps with the second edge section. The polymer bonding agent layer does not extend over any portion of the first edge section such that the conductive layer in the first edge section is immediately adjacent to the conductive layer in the second edge section.

In yet another example embodiment, a coaxial cable includes a center conductor surrounded by a dielectric, a conductive tape surrounding the dielectric, a braid surrounding the conductive tape, and a jacket surrounding the braid. The conductive tape includes a conductive layer and a polymer bonding agent layer immediately adjacent to the conductive layer. The conductive tape defines first and second edge sections that each borders an interior section. A strip of the polymer bonding agent layer covers only a portion of the first edge section and a band of the polymer bonding agent layer covers the second edge section and at least a portion of the interior section. The conductive tape is wrapped around the dielectric with the first edge section overlapping with the second edge section such that a portion of the conductive layer in the first edge section is immediately adjacent to a portion of the conductive layer in the second edge section.

In still another example embodiment, a conductive tape suitable for use in a coaxial cable includes a conductive layer and a bonding agent layer immediately adjacent to the conductive layer. The conductive tape defines first and second edge sections that each borders an interior section such that the conductive tape is capable of being wrapped around a dielectric so that the first edge section overlaps with the second edge section. The bonding agent layer extends over only at most a portion of the first edge section such that, when the first and second edge sections are overlapped, at least a portion of the conductive layer in the first edge section is immediately adjacent to at least a portion of the conductive layer in the second edge section.

This Summary is provided to introduce a selection of concepts in a simplified form that are further described below in the Detailed Description. This Summary is not intended to identify key features or essential characteristics of the claimed subject matter, nor is it intended to be used as an aid in determining the scope of the claimed subject matter. Moreover, it is to be understood that both the foregoing general description and the following detailed description of the present invention are exemplary and explanatory and are intended to provide further explanation of the invention as claimed.

### BRIEF DESCRIPTION OF THE DRAWINGS

Aspects of example embodiments of the present invention will become apparent from the following detailed description of example embodiments given in conjunction with the accompanying drawings, in which:

FIG. 1A is a perspective view of a prior art example coaxial cable terminated with two example connectors;

FIG. 1B is a perspective view of a portion of the prior art coaxial cable of FIG. 1A, the perspective view having portions of each layer of the prior art coaxial cable cut away;

FIG. 1C is a cross-sectional view of the prior art coaxial cable of FIG. 1B;

FIG. 1D is an enlarged view of a portion of the cross-sectional view of FIG. 1C;

FIG. 2A is a perspective view of a portion of an example coaxial cable with a first example conductive tape configuration, the perspective view having portions of each layer of the example coaxial cable cut away;

FIG. 2B is a cross-sectional view of the example coaxial cable of FIG. 2A;

FIG. 2C is an enlarged view of a portion of the cross-sectional view of FIG. 2B;

FIG. 2D is a perspective view of a section of the example conductive tape of FIGS. 2A-2C prior to the inclusion of the example conductive tape as a layer of the example coaxial cable of FIGS. 2A-2C;

FIG. 2E is a cross-sectional view of the example conductive tape of FIG. 2D;

FIG. 2F is an enlarged view of a portion of the cross-sectional view of FIG. 2C with a second example conductive tape configuration; and

FIG. 2G is a cross-sectional view of a section the example conductive tape of FIG. 2F prior to the inclusion of the example conductive tape as a layer of the example coaxial cable of FIG. 2F.

### DETAILED DESCRIPTION OF SOME EXAMPLE EMBODIMENTS

Example embodiments of the present invention relate to coaxial cable shielding. In the following detailed description of some example embodiments, reference will now be made in detail to example embodiments of the present invention which are illustrated in the accompanying drawings. Wherever possible, the same reference numbers will be used throughout the drawings to refer to the same or like parts. These embodiments are described in sufficient detail to enable those skilled in the art to practice the invention. Other embodiments may be utilized and structural changes may be made without departing from the scope of the present invention. Moreover, it is to be understood that the various embodiments of the invention, although different, are not necessarily mutually exclusive. For example, a particular feature, structure, or characteristic described in one embodiment may be included within other embodiments. The following detailed description is, therefore, not to be taken in a limiting sense, and the scope of the present invention is defined only by the appended claims, along with the full scope of equivalents to which such claims are entitled.

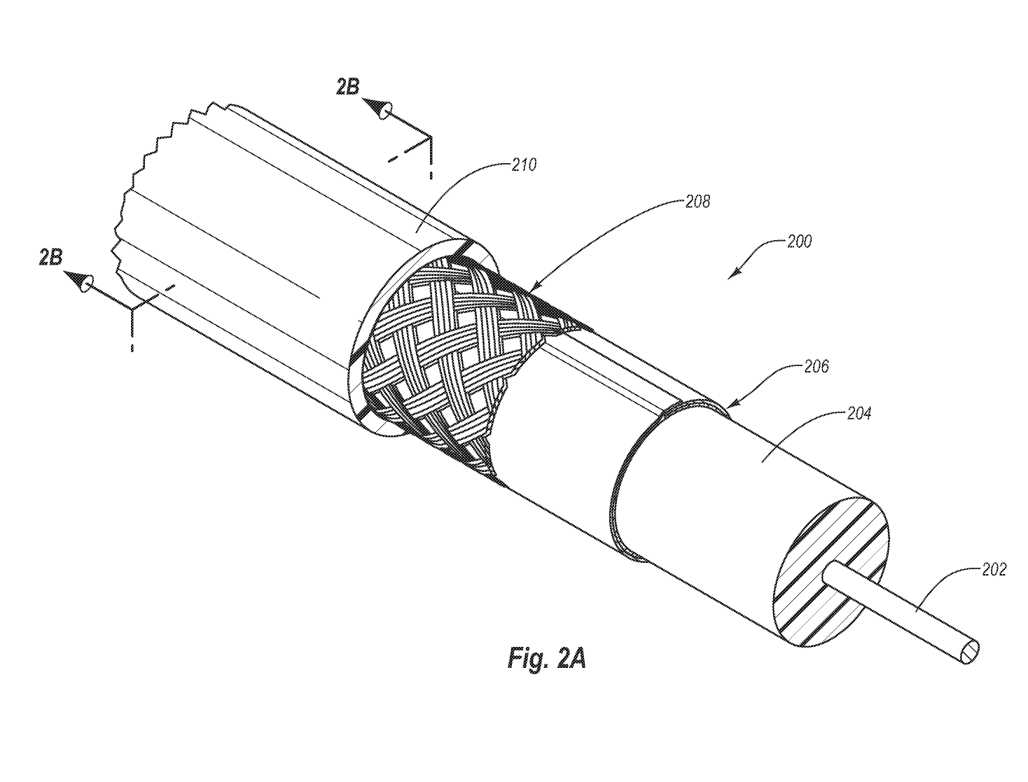

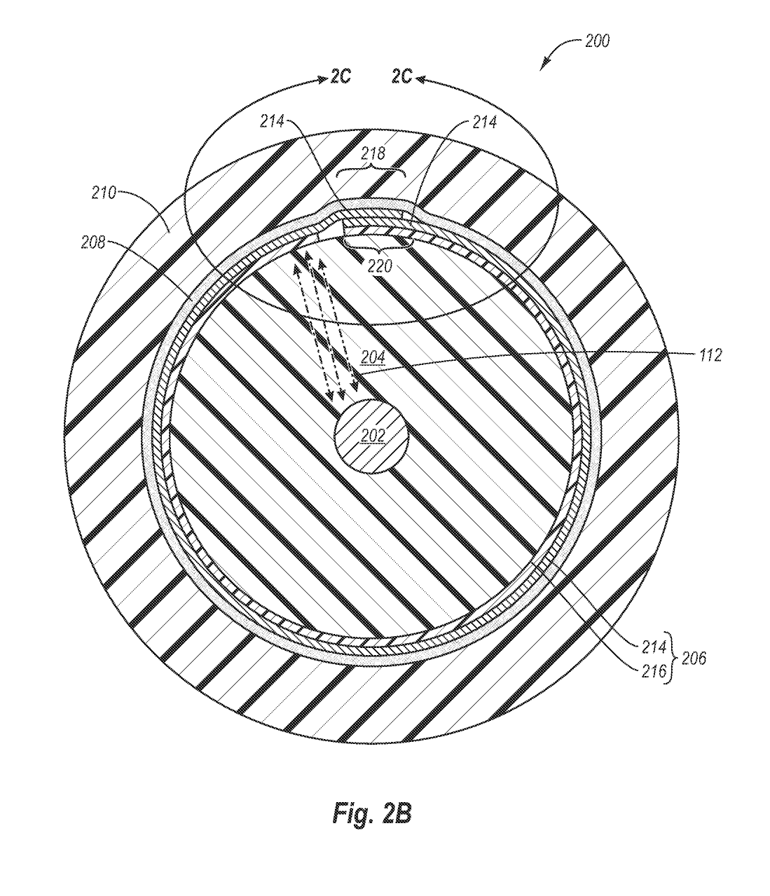

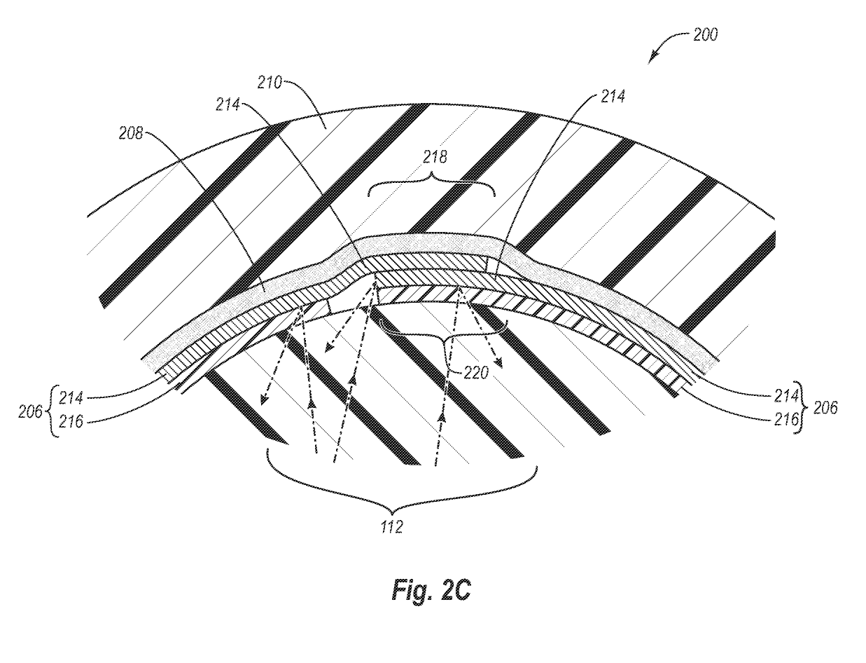

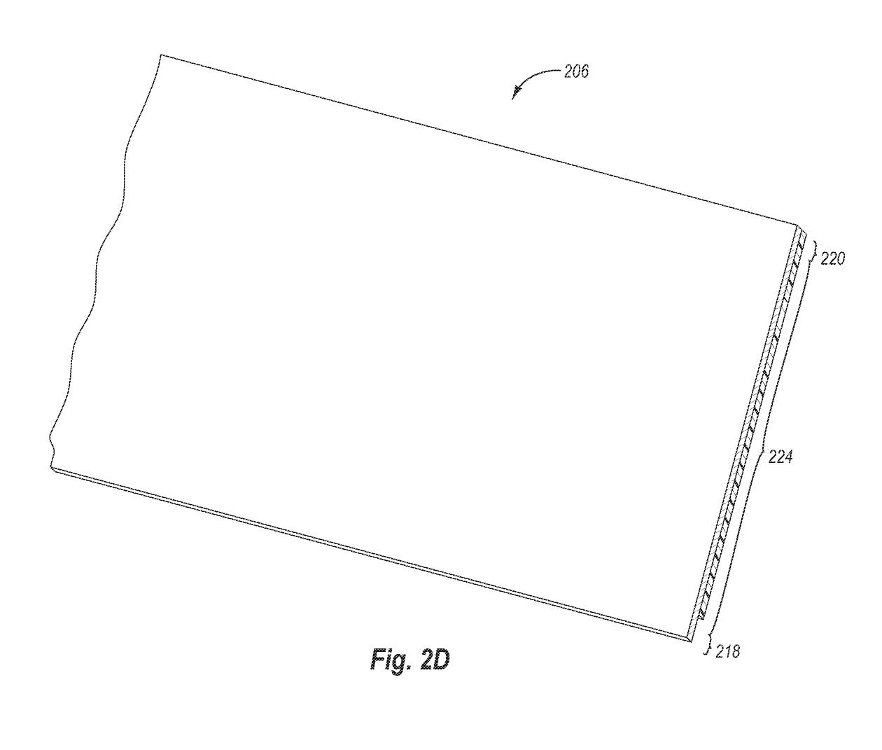

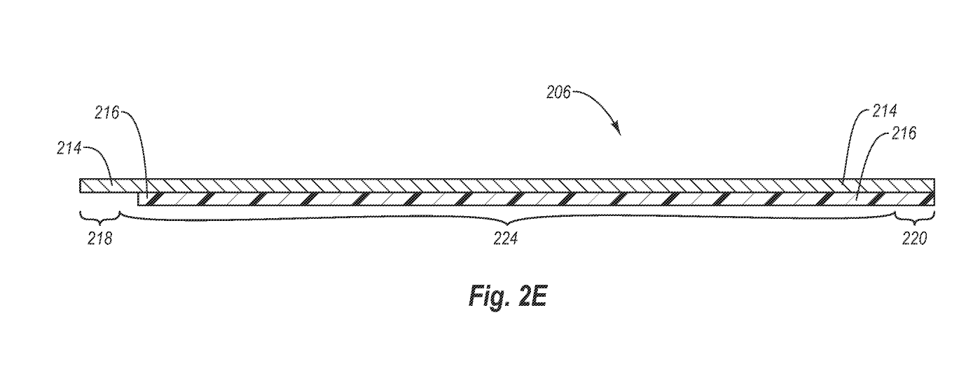

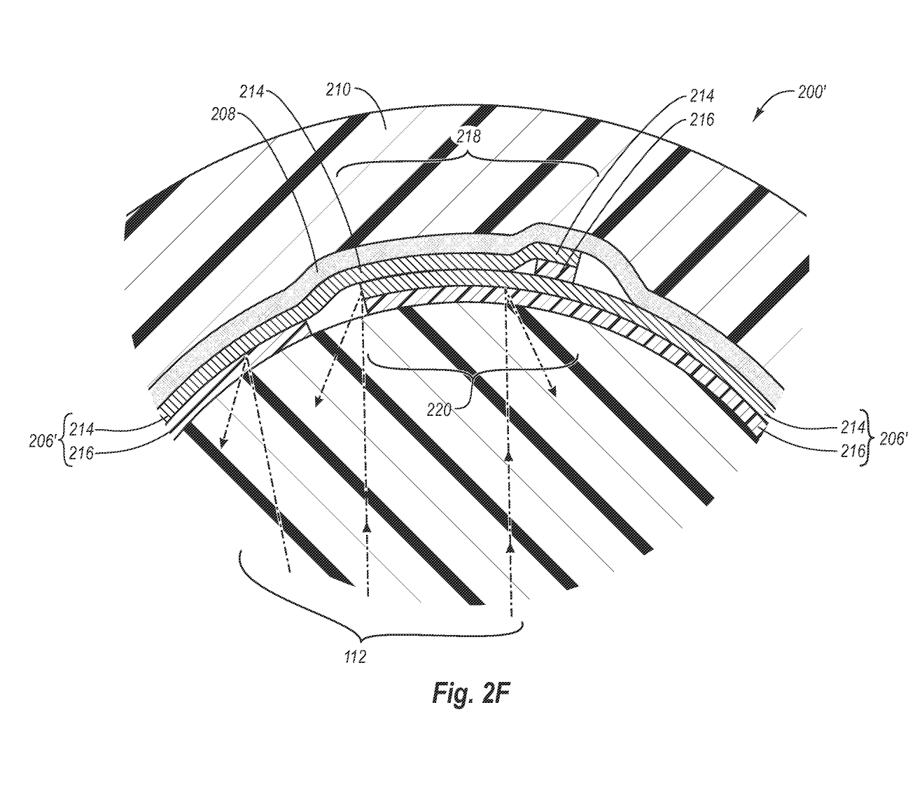

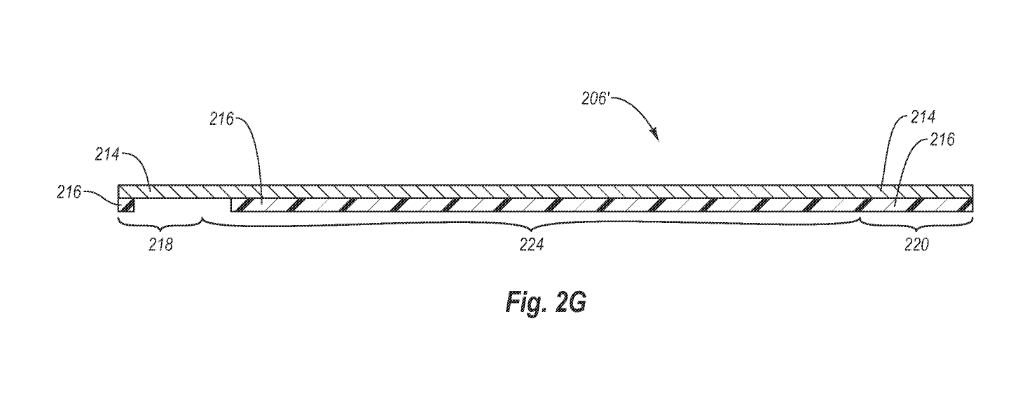

With reference now to FIG. 2A, a first example coaxial cable 200 is disclosed. The example coaxial cable 200 can be any type of coaxial cable including, but not limited to, 50 Ohm and 75 Ohm coaxial cable. The coaxial cable 200 generally includes a center conductor 202 surrounded by a dielectric 204, a conductive tape 206 wrapped longitudinally around the dielectric, a braid 208 surrounding the conductive tape 206, and a jacket 210 surrounding the braid 208. As used herein, the phrase “surrounded by” refers to an inner layer generally being encased by an outer layer. However, it is understood that an inner layer may be “surrounded by” an outer layer without the inner layer being immediately adjacent to the outer layer. The term “surrounded by” thus allows for the possibility of intervening layers. Each of these components of the example coaxial cable 200 will now be discussed in turn.

The center conductor 202 is positioned at the core of the example coaxial cable 200. The center conductor 202 can be configured to carry a range of electrical current (amperes) as well as an RF/electronic digital signal. In some example embodiments, the center conductor 202 is formed from solid copper, copper-clad aluminum (CCA), copper-clad steel (CCS), or silver-coated copper-clad steel (SCCCS), although other conductive materials are possible. For example, the center conductor 202 can be formed from any type of conductive metal or alloy. In addition, the center conductor 202 can be solid, hollow, stranded, corrugated, plated, or clad, for example.

The dielectric 204 surrounds the center conductor 202, and generally serves to support and insulate the center conductor 202 and the conductive tape 206. Although not shown in the figures, a bonding agent, such as a polymer, may be employed to bond the dielectric 204 to the center conductor 202. In some example embodiments, the dielectric 204 can be, but is not limited to, taped, solid, or foamed polymer or fluoropolymer. For example, the dielectric 204 can be foamed polyethylene (PE).

The conductive tape 206 surrounds the dielectric 204, and generally serves to minimize the ingress and egress of high frequency electromagnetic radiation 112 to/from the center conductor 202. In some applications, high frequency electromagnetic radiation is radiation with a frequency that is greater than or equal to about 50 MHz.

With reference now to FIGS. 2B and 2C, the conductive tape 206 is a laminate tape that includes an aluminum layer 214 and a polymer bonding agent layer 216. It is understood, however, that the discussion herein of the conductive tape 206 is not limited to conductive tape having any particular combinations of layers. For example, the conductive tape 206 can instead include, but is not limited to, the following layers: copper/polymer/polymer bonding agent, aluminum/polymer/polymer bonding agent, aluminum/polymer, or aluminum/polymer/aluminum/polymer bonding agent.

With reference now to FIGS. 2D and 2E, the example embodiment of the conductive tape 206 defines first and second edge sections 218 and 220 that each borders an interior section 224. As disclosed in FIGS. 2D and 2E, prior to the conductive tape 206 being wrapped around the dielectric 204, the conductive tape 206 is formed such that the polymer bonding agent layer 216 does not extend over the first edge section 218. In particular, the conductive tape 206 is formed such that there is a bare strip of the aluminum layer 214 along the first edge section 218.

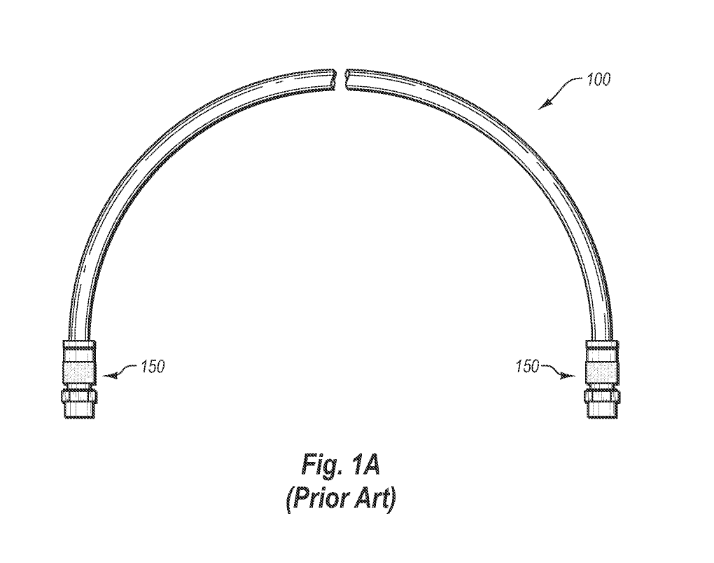

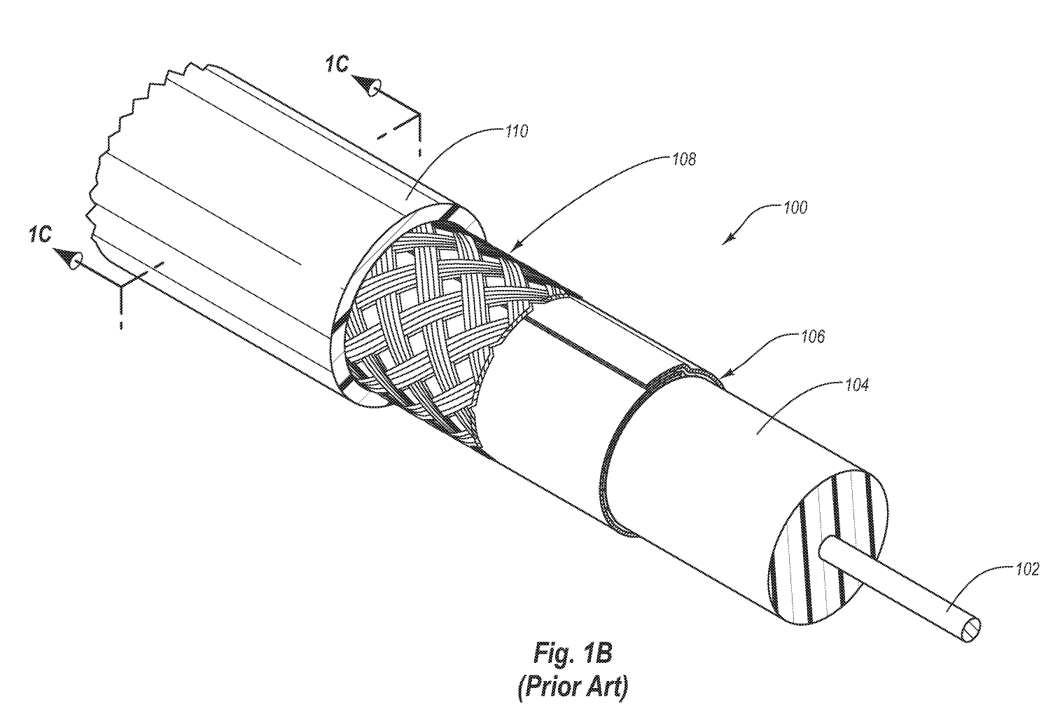

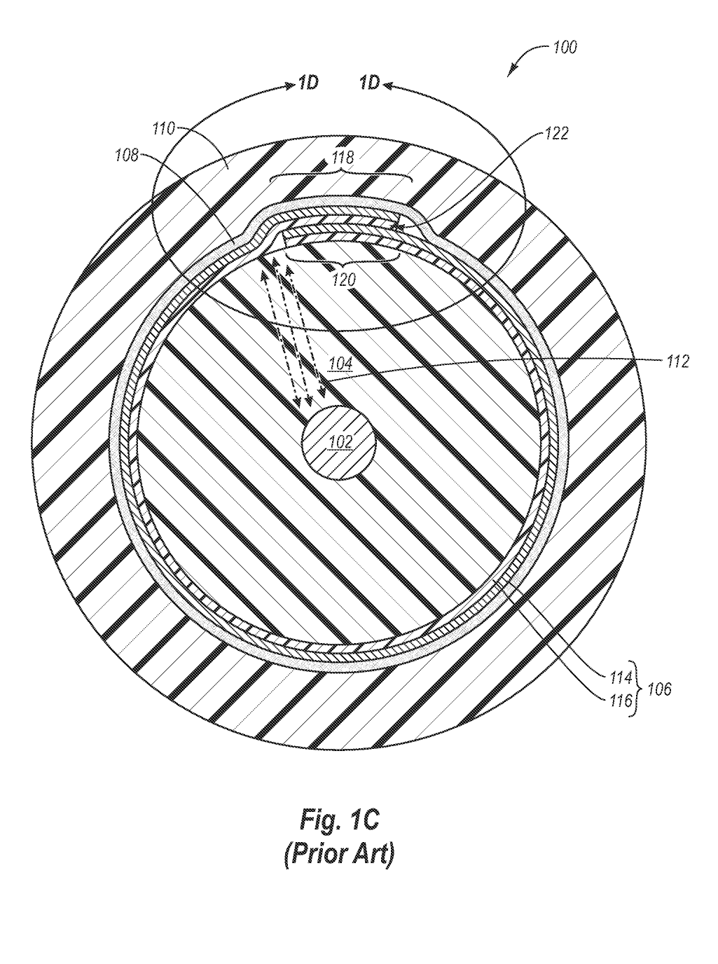

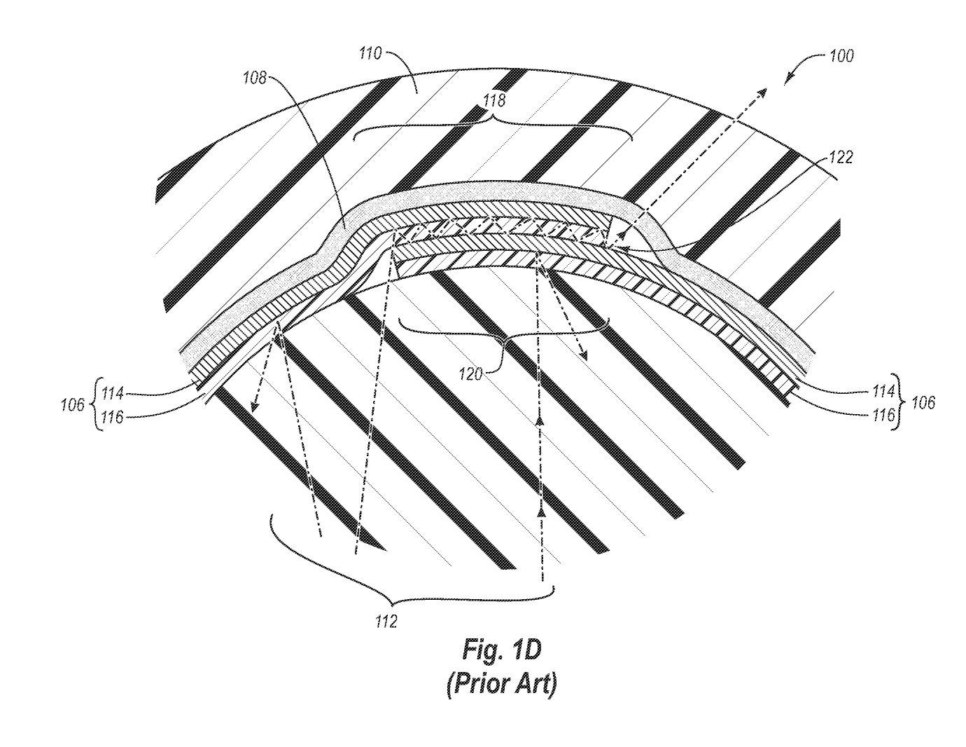

With reference again to FIGS. 2B and 2C, as the conductive tape 206 is longitudinally wrapped around the longitudinal direction of the dielectric 204, the first edge section 218 overlaps with the second edge section 220. As the polymer bonding agent layer 216 is a dielectric layer, and thus is not effective at shielding interfering electromagnetic radiation 112, the absence of the polymer bonding agent layer 216 along the first edge section 218 eliminates entirely the typical overlap aperture in the conductive tape 206 (compare to the overlap aperture 122 of FIG. 1D). The bare strip of the aluminum layer 214 along the first edge section 218 enables the aluminum layer 214 in the first edge section 218 to be immediately adjacent to the aluminum layer 214 in the second edge section 220. This metal-on-metal contact provides very effective shielding at the overlap of the conductive tape 206 against high frequency electromagnetic radiation 112.

For example, compared to the overlap aperture 122 of FIG. 1D, the elimination of an overlap aperture in the overlap of the conductive tape 206 results in less high frequency electromagnetic radiation 112 from the center conductor 202 exiting the example coaxial cable 200. This elimination of the overlap aperture increases the shielding effectiveness of the overlapping edges portions 218 and 220 of the conductive tape 206, which increases the uniformity of the shielding of interfering high frequency electromagnetic radiation in the coaxial cable 200.

It is understood that the benefits of the elimination of overlap apertures noted herein may be achieved with alternative configurations of the conductive tape 206. For example, as disclosed in FIGS. 2F and 2G, an alternative conductive tape 206′ can be formed such that there is a band of the polymer bonding agent layer 216 covering the second edge section 220 and at least a portion of the interior section 224, and a strip of the polymer bonding agent layer 216 along only a portion of the first edge section 218, leaving a bare strip of the aluminum layer 214 along the first edge section 218 and sandwiched in between the strip and the band of the polymer bonding agent layer 216.

As disclosed in FIG. 2F, as the alternative conductive tape 206′ is longitudinally wrapped around the longitudinal direction of the dielectric 204, the first edge section 218 overlaps with the second edge section 220. The absence of the polymer bonding agent layer 216 along a portion of the first edge section 218 eliminates entirely the typical overlap aperture in the conductive tape 206 (compare to the overlap aperture 122 of FIG. 1D). The bare strip of the aluminum layer 214 along the portion of the first edge section 218 enables the aluminum layer 214 in the first edge section 218 to be immediately adjacent to the aluminum layer 214 in the second edge section 220. This metal-on-metal contact provides very effective shielding at the overlap of the conductive tape 206 against high frequency electromagnetic radiation 112. Further, the strip of polymer bonding agent layer 216 along the first edge section 218 secures the top edge section 218 to the bottom edge section 220 of the alternative conductive tape 206′.

The benefits of the elimination of overlap apertures noted herein may also be achieved with other alternative configurations of the conductive tape 206 and/or the coaxial cable 200. For example, another alternative conductive tape that includes multiple layers of aluminum and polymer (not shown) may have at least a portion of the polymer layers absent in an overlapping edge section in order to allow each of the aluminum layers to achieve metal-on-metal contact, thus eliminating overlap apertures in the conductive tape.

With reference again to FIG. 2A, the braid 208 surrounds the conductive tape 206, and generally serves to minimize the ingress and egress of electromagnetic radiation to/from the center conductor 202. In addition, the braid 208 also serves to give structural support to, and thereby strengthen, the coaxial cable 200. The braid 208 can be formed, for example, from inter-woven, fine gauge aluminum or copper wires, such as 34 American wire gauge (AWG) wires. Although the braid wires of the braid 208 are depicted as single wires in FIG. 2A, each wire actually represents several round 34 AWG wires. It is understood, however, that the discussion herein of braid is not limited to braid formed from any particular type, size, and/or number of wires. It is further noted that the braid 208 provides a radial inward pressure on the conductive tape 206, or the alternative conductive tape 206′, thus allowing the aluminum layer 214 of the conductive tapes to achieve secure metal-to-metal contact along the overlap of the conductive tapes.

With continuing reference to FIG. 2A, the jacket 210 surrounds the braid 208, and generally serves to protect the internal components of the coaxial cable 200 from external contaminants, such as dust, moisture, and oils, as well as wear and tear over time, for example. The jacket 210 can be formed from materials such as, but not limited to, polyethylene (PE), high-density polyethylene (HDPE), low-density polyethylene (LDPE), or linear low-density polyethylene (LLDPE), foamed PE, polyvinyl chloride (PVC), or polyurethane (PU), or some combination thereof.

The benefits of the elimination of overlap apertures noted herein may also be achieved with alternative configurations of the coaxial cable 200. For example, although the example embodiments are described in the context of a standard coaxial cable, it is understood that other cable configurations may likewise benefit from the conductive tape 206 and/or the alternative conductive tape 206′ disclosed herein. For example, single-shield cable (where the cable include only a single conductive tape layer), tri-shield cable (where the cable includes one braid layer and two conductive tape layers), quad-shield cable (where the cable includes two braid layers and two conductive tape layers), and messengered coaxial cable (where the cable includes a messenger wire embedded in the jacket that provides support in situations where the cable aerially spans long distances, such as 75 feet or more) can be configured to include the conductive tape 206 or the alternative conductive tape 206′. Further, flooded coaxial cables can be configured to include the conductive tape 206 and/or the alternative conductive tape 206′. It is further understood that cable configurations having two or more conductive tape layers immediately adjacent to one another and/or two or more braid layers immediately adjacent to one another can be configured to include the conductive tape 206 or the alternative conductive tape 206′.

In addition, coaxial cables with helically wrapped conductive tape can likewise be configured to have metal-on-metal edge sections similar to the edge sections 218 and 220 of the conductive tape 206. These metal-on-metal edge sections eliminate overlap apertures that run in a helical course along the face of the top portion of the helically wrapped conductive tape. This elimination of the overlap apertures will increase the shielding effectiveness of the helically wrapped conductive tape at or near the overlap, and will further result in an increase in the uniformity of the shielding of interfering high frequency electromagnetic radiation in the coaxial cable.

The example embodiments disclosed herein may be embodied in other specific forms. The example embodiments disclosed herein are to be considered in all respects only as illustrative and not restrictive.

What is claimed is:

1. A coaxial cable comprising:
a center conductor surrounded by a dielectric;
a conductive tape surrounding the dielectric, the conductive tape comprising a conductive layer and a bonding agent layer immediately adjacent to the conductive layer, the conductive tape defining first and second edge sections that each borders an interior section, the conductive tape being wrapped around the dielectric such that the first edge section overlaps with the second edge section, the bonding agent layer extending over only at most a portion of the first edge section such that at least a portion of the conductive layer in the first edge section is immediately adjacent to at least a portion of the conductive layer in the second edge section; and
a jacket surrounding the conductive tape.

2. The coaxial cable as recited in claim 1, wherein the bonding agent layer does not extend over any portion of the first edge section.

3. The coaxial cable as recited in claim 1, wherein the entire conductive layer in the first edge section is immediately adjacent to the entire conductive layer in the second edge section.

4. The coaxial cable as recited in claim 1, wherein the conductive tape further comprises:
a strip of the bonding agent layer covering only a portion of the first edge section; and
a band of the bonding agent layer covering the second edge section and at least a portion of the interior section.

5. The coaxial cable as recited in claim 1, wherein the conductive tape further comprises a polymer layer immediately adjacent to the conductive layer.

6. The coaxial cable as recited in claim 5, wherein the conductive tape further comprises a second conductive layer immediately adjacent to the polymer layer.

7. The coaxial cable as recited in claim 1, further comprising a braid that surrounds the conductive tape and that is surrounded by the jacket.

8. A coaxial cable comprising:
a center conductor surrounded by a dielectric;
a conductive tape surrounding the dielectric, the conductive tape comprising a conductive layer and a polymer bonding agent layer immediately adjacent to the conductive layer, the conductive tape defining first and second edge sections that each borders an interior section, the conductive tape being wrapped around the dielectric such that the first edge section overlaps with the second edge section, the polymer bonding agent layer not extending over any portion of the first edge section such that the conductive layer in the first edge section is immediately adjacent to the conductive layer in the second edge section;
a braid surrounding the conductive tape; and
a jacket surrounding the braid.

9. The coaxial cable as recited in claim 8, wherein the conductive tape further comprises:
a second polymer layer immediately adjacent to the conductive layer; and
a second conductive layer immediately adjacent to the second polymer layer.

10. The coaxial cable as recited in claim 9, wherein the second polymer layer extends over only at most a portion of the first edge section such that at least a portion of the second conductive layer in the first edge section is immediately adjacent to at least a portion of the conductive layer in the first edge section.

11. The coaxial cable as recited in claim 8, further comprising a second conductive tape that surrounds the braid and that is surrounded by the jacket.

12. The coaxial cable as recited in claim 11, further comprising a second braid that surrounds the second conductive tape and that is surrounded by the jacket.

13. The coaxial cable as recited in claim 8, further comprising a messenger wire embedded in the jacket.

14. A coaxial cable comprising:
a center conductor surrounded by a dielectric;
a conductive tape surrounding the dielectric, the conductive tape comprising a conductive layer and a polymer bonding agent layer immediately adjacent to the conductive layer, the conductive tape defining first and second edge sections that each borders an interior section, a strip of the polymer bonding agent layer covering only a portion of the first edge section and a band of the polymer bonding agent layer covering the second edge section and at least a portion of the interior section, the conductive tape being wrapped around the dielectric with the first edge section overlapping with the second edge section such that a portion of the conductive layer in the first edge section is immediately adjacent to a portion of the conductive layer in the second edge section;
a braid surrounding the conductive tape; and
a jacket surrounding the braid.

15. The coaxial cable as recited in claim 14, wherein the conductive layer comprises an aluminum layer and the conductive tape further comprises a second polymer layer immediately adjacent to the aluminum layer.

16. The coaxial cable as recited in claim 15, wherein the conductive tape further comprises a second aluminum layer immediately adjacent to the second polymer layer.

17. The coaxial cable as recited in claim 16, wherein the second polymer layer extends over only at most a portion of the first edge section such that at least a portion of the second aluminum layer in the first edge section is immediately adjacent to at least a portion of the aluminum layer in the first edge section.

18. The coaxial cable as recited in claim 14, further comprising a second conductive tape that surrounds the braid and that is surrounded by the jacket.

19. The coaxial cable as recited in claim 18, further comprising a second braid that surrounds the second conductive tape and that is surrounded by the jacket.

20. The coaxial cable as recited in claim 14, further comprising a messenger wire embedded in the jacket.

21. A conductive tape suitable for use in a coaxial cable, the conductive tape comprising:
a conductive layer; and
a bonding agent layer immediately adjacent to the conductive layer,
wherein the conductive tape defines first and second edge sections that each borders an interior section such that the conductive tape is capable of being wrapped around a dielectric so that the first edge section overlaps with the second edge section, and
wherein the bonding agent layer extends over only at most a portion of the first edge section such that, when the first and second edge sections are overlapped, at least a portion of the conductive layer in the first edge section is immediately adjacent to at least a portion of the conductive layer in the second edge section.

22. The conductive tape as recited in claim 21, wherein the conductive layer comprises an aluminum layer and the bonding agent layer comprises a polymer bonding agent layer.
